(19) United States
(12) Patent Application Publication
(10) Pub. No.: US 2011/0306170 A1
(43) Pub. Date: Dec. 15, 2011

(54) Novel Method to Improve Performance by Enhancing Poly Gate Doping Concentration in an Embedded SiGe PMOS Process

(75) Inventors: Xin WANG, New York, NY (US); Zhiqiang WU, Allen, TX (US); Weize XIONG, Austin, TX (US); Song Zhao, Plano, TX (US)

(73) Assignee: TEXAS INSTRUMENTS INCORPORATED, Dallas, TX (US)

(21) Appl. No.: 12/549,908

(22) Filed: Aug. 28, 2009

Related U.S. Application Data
(60) Provisional application No. 61/093,031, filed on Aug. 29, 2008.

(51) Int. Cl. H01L 21/336

(52) U.S. Cl. 438/197; 257/E21.409

(57) ABSTRACT

A method for forming an embedded SiGe (eSiGe) PMOS transistor (102) with improved PMOS poly gate (108) doping concentration without increasing mask count and causing S/D overrun issue. After gate sidewall spacer (112) formation, the gate electrode (108) and source/drain regions (122) are implanted. After the implant, a recess (124) is formed and SiGe is deposited in the recess. By implanting and removing the implanted material (122) from the source/drain regions prior to SiGe (106) deposition, high PMOS gate doping can be achieved without causing a S/D overrun issue.

### RELATED APPLICATION

This application claims the priority of U.S. Provisional Application Ser. No. 61/093,031, filed Aug. 29, 2008, entitled “Novel Method to Improve Performance by Enhance Poly Gate Doping Concentration in an Embedded SiGe PMOS Process”.

This application is related to co-pending U.S. application Ser. No. ______ (TI-66902), filed ______, and entitled “DISPOSABLE SPACER INTEGRATION WITH STRESS MEMORIZATION TECHNIQUE AND SILICON-GERMANIUM”.

### FIELD OF THE INVENTION

The invention is generally related to the field of forming transistors in semiconductor devices and more specifically to improving performance in a PMOS transistor.

### BACKGROUND OF THE INVENTION

Historically, most performance improvements in semiconductor field-effect transistors (FET) have been achieved by scaling down the relative dimensions of the device. This trend is becoming increasingly more difficult to maintain as the devices reach their physical scaling limits. As a consequence, advanced FETs and the complementary metal oxide semiconductor (CMOS) circuits in which they can be found are increasingly relying on strain engineering and specialty silicon-on-insulator substrates to achieve desired circuit performance.

One method of introducing compressive strain in a silicon channel region is to epitaxially grow a silicon-germanium (SiGe) material within recesses formed in the semiconductor body. The silicon germanium atom has a different lattice spacing than the silicon atom thereby imparting a compressive strain to the channel region under the gate. This is referred to as an embedded SiGe process.

As with more conventional transistors, high poly gate doping concentration improves on-state current in metal oxide semiconductor transistors. It is common for integrated circuits (ICs) to pre-dope poly gate over the PMOS transistors or increase PMOS source/drain (S/D) implant dose and (or) energy to increase doping concentration in poly gate. Pre-doping poly gate requires additional mask level to block p-type implant from NMOS region. High PMOS S/D implant dose increases the S/D overrun risk, which increases leakage current, and increases the SiGe relaxation caused by S/D implant.

Improved performance in PMOS transistors fabricated using an embedded SiGe process is desired.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

The invention provides a novel embedded SiGe (eSiGe) PMOS process to improve PMOS poly gate doping concentration without increasing mask count and causing S/D overrun issue. After gate sidewall spacer formation, the gate electrode and source/drain regions are implanted. After the implant, a recess is formed and SiGe is deposited in the recess. By implanting and removing the implanted material from the source/drain regions prior to SiGe deposition, high PMOS gate doping can be achieved without causing a S/D overrun issue.

An advantage of the invention is providing an embedded SiGe process with improved PMOS transistor performance.

This and other advantages will be apparent to those of ordinary skill in the art having reference to the specification in conjunction with the drawings.

### BRIEF DESCRIPTION OF THE DRAWINGS

In the drawings:

FIG. 1 is a cross-sectional diagram of a PMOS transistor according to an embodiment of the invention;

FIG. 2A-2D are cross-sectional diagrams of the PMOS transistor of FIG. 1 at various stages of fabrication.

### DETAILED DESCRIPTION OF THE EMBODIMENTS

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

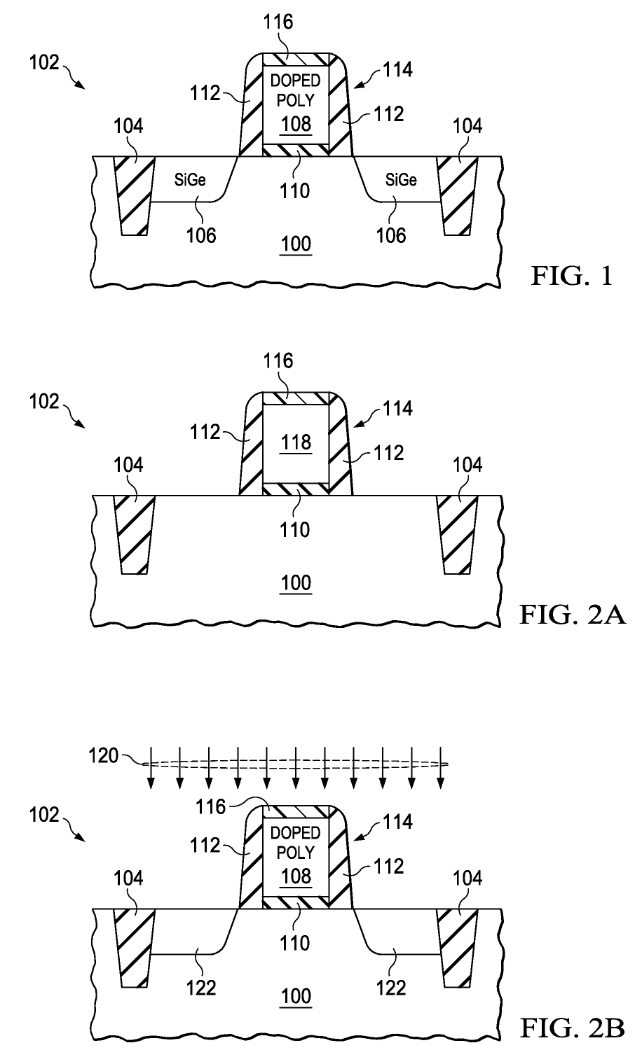

The invention will now be described in conjunction with an embedded SiGe PMOS transistor and its fabrication. FIG. 1 illustrates an embedded SiGe PMOS transistor 102 formed in a substrate 100. Substrate 100 is typically p-type single crystal silicon, but possibly a silicon-on-insulator (SOI) wafer which has a layer of single crystal silicon over a buried insulating layer, or a hybrid orientation technology (HOT) wafer which has regions of different crystal orientation for different components, or any other substrate which supports fabrication of integrated circuits. Isolation regions 104 isolate transistor 102 from other devices (not shown) formed in substrate 100. SiGe source and drain regions 106 are located in substrate 100 on opposing sides of gate structure 114. Gate structure 114 comprises a gate electrode 108 over a gate dielectric 110 with sidewall spacers 112. Gate dielectric 110 is typically silicon dioxide, nitrogen doped silicon dioxide, silicon oxy-nitride, hafnium oxide, layers of silicon dioxide and silicon nitride, or other insulating material, between 1 and 5 nanometers thick. Sidewall spacers 112 are located on the sidewalls of gate electrode 108 and may comprise one or more layers of silicon nitride and/or silicon dioxide.

Gate electrode 108 comprises highly doped p-type polysilicon. High polysilicon gate doping concentration improves on-state current. The doping concentration of gate electrode 108 may be in the range of 10²⁰/cm³ to 10e²¹/cm³. Advantageously, gate electrode 108 is highly doped without excessively doping the SiGe source/drain regions 106, thus avoiding a dopant overrun issue (e.g., increased leakage current, and/or increased SiGe relaxation caused by S/D implant).

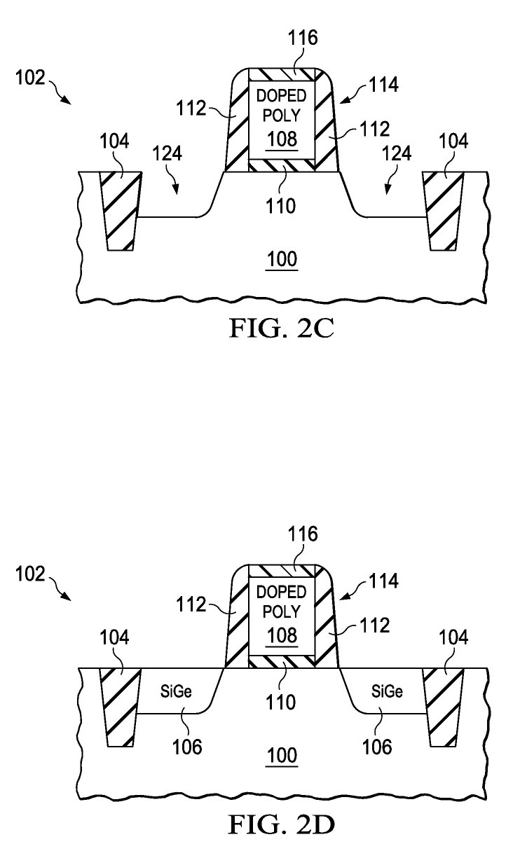

A process for forming the embedded SiGe PMOS transistor of FIG. 1 will now be discussed with reference to FIGS. 2A-2E and FIG. 3. Substrate 100 is processed through the formation of sidewall spacers 112, as shown in FIG. 2A. For example, isolation regions 104 may be formed by a shallow trench isolation (STI) process sequence, in which trenches, commonly 200 to 500 nanometers deep, are etched into the substrate 100, electrically passivated, commonly by growing a thermal oxide layer on sidewalls of the trenches, and filled with insulating material, typically silicon dioxide, commonly by a high density plasma (HDP) process or an ozone based thermal chemical vapor deposition (CVD) process, also known as the high aspect ratio process (HARP). Isolation regions 104 isolate an area defined for PMOS transistor 102 from other devices to be formed in substrate 100. Gate dielectric 110, typically silicon dioxide, nitrogen doped silicon dioxide, silicon oxy-nitride, hafnium oxide, layers of silicon dioxide and silicon nitride, or other insulating material, between 1 and 5 nanometers thick, is formed on a top surface of substrate 100, using known methods of gate dielectric layer formation. Gate electrode material 118, typically undoped polysilicon is deposited over gate dielectric 110. Hard mask 116 is deposited over gate electrode material 118. The hard mask may, for example, comprise silicon nitride. The gate dielectric 110, gate electrode material 118 and hard mask 116 are then patterned and etched to form gate structure 114. PLDD regions (not shown) may optionally be included as is known in the art. Alternatively, the PLDD regions may be formed after formation of the source/drain implanted regions 122 discussed below.

Still referring to FIG. 2A, sidewall spacers 112 are formed on the sidewalls of the gate structure 114, typically by deposition of one or more conformal layers of silicon nitride and/or silicon dioxide followed by removal of the conformal layer material from the horizontal surfaces by known anisotropic etching methods, leaving the conformal layer material on the lateral surfaces of gate structure 114.

Instead of forming recesses in substrate 100 for the SiGe source/drain regions immediately after forming sidewall spacers 112, the inventive process flow performs a source/drain implant with high dose and energy. Referring to FIG. 2B, p-type dopant 120 is implanted into previously undoped gate electrode material 118 and the substrate 100, thus forming implanted regions 122 in the source/drain areas of transistor 102 and doped gate electrode 108. The dopant energy and dose are selected to achieve a high dopant level in gate electrode 108 for improved transistor performance without the need to balance the gate doping level with the desired source/drain dopant level. For example, boron, sometimes partly in the form BF₂, and possibly indium and/or gallium, may be implanted at a total dose between 3·10¹⁴ and 2·10¹⁶ atoms/cm².

Next, a masked silicon recess etch is performed to remove portions of the substrate where PMOS source/drain regions are desired. As a result, the implanted regions 122 are removed as shown in FIG. 2C. In one realization of the instant embodiment, the recess process may include a fluorine containing RIE process. Other processes for forming the recesses 124 are within the scope of the instant embodiment. The recesses 124 are deeper that implanted regions 122 by at least 30 nm beyond the implant peak and may be between 50 and 120 nanometers deep. In one realization, the recesses 124 may be between 70 and 100 nanometers deep. During the silicon recess etch, gate electrode 108 is protected from the etch by hard mask 116. This etch removes silicon as well as at least a majority of the dopant implanted during the source/drain implant. Consequently, the effects of the high dopant dose and energy needed to provide a highly dopant gate electrode 108 are mitigated and/or eliminated from the source/drain regions.

In a first embodiment of the invention, recesses 124 are then filled with SiGe to form embedded SiGe source/drain (S/D) regions 106 as shown in FIG. 2d. The SiGe is deposited by epitaxial deposition into recesses 124 to form S/D regions 106. S/D regions 106 may be in-situ doped during deposition. For example the substrate 100 may be heated to a temperature between 600 C and 700 C, while exposing an existing top surface of the substrate 100 to an epitaxial growth ambient containing silicon, germanium, boron and possibly carbon. This epitaxial growth ambient may be formed, for example, by flowing at least 5 slm of hydrogen gas, flowing between 50 standard cubic centimeters per minute (sccm) and 150 sccm of dichlorosilane gas, flowing between 30 sccm and 200 sccm of a gas mixture of between 5 and 10 percent germane gas and a carrier gas such as hydrogen, flowing between 50 sccm and 200 sccm of a gas mixture of between 0.25 percent and 2 percent of methylsilane and a carrier gas such as hydrogen, flowing between 50 sccm and 100 sccm hydrogen chloride gas, and flowing between 50 sccm and 200 sccm of a gas mixture of between 0.5 percent and 1 percent of diborane and a carrier gas such as hydrogen, into the epitaxial growth ambient at a pressure between 5 torr and 20 torr. In one realization of the instant embodiment, the substrate 100 may be heated to a temperature between 640 C and 660 C. In one realization of the instant embodiment, a germanium content of the S/D regions 106 may be between 20 atomic percent and 30 atomic percent. A carbon density of the source/drain regions 106 is between 5×10¹⁹ and 1×10²⁰ atoms/cm³ and a boron density is at least 5×10¹⁹ atoms/cm³. Other methods known in the art for forming embedded SiGe source/drain regions may alternatively be used to form SiGe S/D regions 106.

After the SiGe deposition, an anneal may be performed to activate the implanted dopants in the Si. The anneal is typically done with 1000 C to 1050 RTA for a few seconds or laser anneal at 1200 C-1300 C for a few milli-seconds.

Alternatively, the anneal may be performed prior to epitaxially depositing SiGe to form source/drain regions 106. An advantage of performing the anneal first is reduce the chances of SiGe relaxation during anneal. Conversely, an advantage of performing the anneal last is to reduce the diffusion of PMOS S/D implanted dopants. This help to ensure the PMOS S/D dopants are etched away during the recess etch.

Processing may continue as is known in the art with the removal of hard mask 114, formation of silicide regions at the surface of the gate electrode 108 and source/drain regions 106, the formation of contacts and interconnect layers as well as packaging of the device.

It should be noted that while the above process described the formation of a PMOS transistor, NMOS transistors and other devices may be formed concurrently with PMOS transistor 102.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method of fabricating an integrated circuit comprising the steps of:
forming a gate structure over a substrate, wherein said gate structure comprises a polysilicon gate electrode;
performing a source/drain implant to introduce dopants to said polysilicon gate electrode and form an implant region in a source/drain region of said substrate;
after performing said source/drain implant, forming a recess in said substrate by removing said implant region in the source/drain region;
filling said recess with p-type doped SiGe; and
annealing said substrate to form an embedded SiGe PMOS transistor.

2. The method of claim 1, wherein said filling step occurs prior to said annealing step.

3. The method of claim 1, wherein said annealing step occurs prior to said filling step.

4. The method of claim 1, wherein performing the source/drain implant comprises implanting a p-type dopant at a dopant density of 10²⁰/cm³ to 10e²¹/cm³ in said polysilicon gate electrode.

5. A method of fabricating a PMOS transistor comprising the steps of:
forming a gate structure having an undoped polysilicon gate electrode over a substrate;
forming sidewall spacers adjacent said gate structure;
performing an implant of p-type dopants into a source/drain region of the substrate to create an implanted region and into the undoped polysilicon gate electrode to form a doped polysilicon gate electrode, wherein said implant is of a sufficient dose and energy to create a dopant density of 10²⁰/cm³ to 10e²¹/cm³ in said doped polysilicon gate electrode;
after performing said implant, forming a recess in said substrate by removing said implanted region of said substrate;
filling said recess with p-type doped SiGe; and
annealing said substrate.
